(19) United States
(12) Patent Application Publication
(10) Pub. No.: US 2005/0201490 A1
(43) Pub. Date: Sep. 15, 2005

(54) Zero-crossing detector for receivers

(76) Inventors: Tobias Scholand, Mulheim a.d.R. (DE); Peter Jung, Duisburg (DE)

Correspondence Address: Richard C. Woodbridge, Esq.;Synnestvedt Lechner & Woodbridge, LLP, P.O. Box 592, Princeton, NJ, 08542-0592, US

(21) Appl. No.: 10/783,063

(22) Filed: Feb. 20, 2004

(51) Int. Cl. H03D 3/00

(52) U.S. Cl. 375/322

(57) ABSTRACT

A system and method of demodulating digital phase-modulated signals using zero-crossing detection at an appropriate intermediate frequency (IF). The input signal is filtered with an analog bandpass filter. The IF is chosen so that an appropriate linear digital filter applied to the output results in significantly improved Bit Error Rate (BER) of the recovered data signal. A microprocessor may be used to sample the incoming signal with its Timer Input. A Zero-Crossing-Detector detects the change of the sign of the signal with a one bit AD-converter. An effective low bit resolution, given by the timer frequency, is demanded. A resolution of only 2 to 5 bits for the time variation values of the zero-crossing intervals (spaces) δ is necessary for the digital filters to operate with high accuracy. The receiver can use either a linear or non-linear system model for its digital filter.

### BACKGROUND OF THE INVENTION

1. Field of the Invention

The present invention relates to frequency-modulated digital radio receivers, and particularly to receivers in which demodulation of the signal includes zero-crossing detection.

2. Description of the Related Art

Bluetooth is a short-range wireless communication system facilitating ad-hoc networking between various devices and terminals which uses a digital frequency modulation (FM) scheme termed GFSK (Gaussian Frequency Shift Keying). Like GMSK (Gaussian Minimum Shift Keying), GFSK is a continuous phase modulation (CPM) scheme. As Bluetooth is intended as a low cost, consumer product, it is highly desirable to have receivers and related hardware that are inexpensive yet capable of establishing high quality links. This requires receiver methods and systems that are simple and robust.

Usually, receiver structures are based on a conventional system model as described by, for instance, Park et al. “Channel estimation and DC-offset compensation schemes for frequency-hopped Bluetooth networks” in IEEE Communications Letters, vol. 5 (2001), pp. 4-6, the contents of which are hereby incorporated by reference. Unfortunately, the corresponding receivers are rather elaborate.

An alternative approach to designing receivers for such signals makes use of zero-crossing demodulation and provides low implementation complexity. Such systems using zero-crossing detection of the complex valued received signal demodulated to the base band have been described by, for instance, Dutta et al in “Low power frequency-to-time conversion for cellular systems using predictive zero-crossing”, Proceedings of the 47th IEEE Vehicular Technology Conference (VTC '97), Phoenix/AZ, pp. 1074-1078, 1997, the contents of which are hereby incorporated by reference. Because of the low implementation complexity, such receivers have been considered for use in systems such as Bluetooth. However, the zero-crossing receivers described above suffer considerable performance degradation.

What is needed is a system that combines the low complexity implementation of a zero-crossing receiver with sufficiently high quality performance to provide inexpensive yet robust receivers capable establishing high quality wireless links.

### SUMMARY OF THE INVENTION

The present invention is system and method of detecting signals in digital phase modulated signals. In a preferred embodiment, the system operates using zero-crossing detection of a real-valued received signal prevailing at an appropriately chosen intermediate frequency (IF). The input signal is filtered with an appropriate analog bandpass filter. The IF is chosen so that an appropriately chosen linear digital filter applied to the output results in a significantly improved Bit Error Rate (BER) of the recovered data signal.

In a preferred embodiment, a standard microprocessor is used to sample the incoming signal s(t) with its Timer Input or a normal Input. This corresponds to a 1-bit AD-converter. The obtained resolution is given by the timer frequency of the microprocessor. It is the idea of this invention to use only a Zero-Crossing-Detector which detects the change of the sign of the signal with an effective low bit resolution. It was found out that a resolution of only 2 to 5 bits for the time variation values of the zero-crossing intervals (spaces) δ is necessary for the used filters of the estimator to detect the transmitted signals with a high accuracy. Conventional base-and receiver techniques require AD-converters with a much higher resolution.

The invented receiver can use a linear or non-linear system model for its estimator (digital filter) to calculate the probability of the accuracy of the detected transmitted and received signals.

An object of the present invention to provide a receiver for modulated signals—not only for Bluetooth signals—which needs only inexpensive hardware with a low power consumption which can be implemented in mobile devices such as mobile phones.

### BRIEF DESCRIPTION OF THE DRAWINGS

FIG. 1 shows a conventional receiving circuit for a phase-modulated digital signal in which the received signal is demodulated to the base-band.

FIG. 2 shows a receiving circuit for a phase-modulated digital signal in which the received signal is demodulated at first to an intermediate frequency and then to the base-band.

FIG. 3 shows a zero-crossing receiving circuit for a phase-modulated digital signal in which a sample and hold circuit is use to recover the data signal.

FIG. 4 shows an exemplary zero-crossing receiving circuit embodying the inventive concepts of the present invention.

FIG. 5 shows an exemplary zero-crossing receiving circuit embodying the inventive concepts of the present invention implemented as functional modules of an integrated circuit.

FIG. 6 shows a parallel multi-standard capable zero-crossing receiver.

FIG. 7 shows a serial multi-standard capable zero-crossing receiver.

FIG. 8 shows the elements of a representative output filter.

FIG. 9 shows representative results of a receiving circuit embodying the inventive concepts of the present invention.

### DETAILED DESCRIPTION

Many modern wireless communications systems such as, but not limited to, the well-known Bluetooth and DECT (Digital Enhanced Cordless Telecommunications) utilize a continuous phase modulation (CPM) scheme termed GFSK (Gaussian Frequency Shift Keying) which, as a generalization of GMSK (Gaussian Minimum Shift Keying) which in turn was developed by setting out from MSK (Minimum Shift Keying). MSK has been adopted for the Differential Global Positioning System (DGPS). GFSK is used in Bluetooth and Global System for Mobile communications (GSM) systems.

All these systems would benefit from the availability of inexpensive, simple but powerful receivers. However, the usual receivers designed for such signals are quite elaborate structures, based on a conventional system model as described by, for instance, Park et al. “Channel estimation and DC-offset compensation schemes for frequency-hopped Bluetooth networks” in IEEE Communications Letters, vol. 5 (2001), pp. 4-6.

An alternative to these conventional receivers are zero-crossing detectors, which have paved the way to irregular sampling and therefore represent a rather unconventional point of view of data detection. Standard zero-crossing detectors can be implemented simply and cheaply, but suffer from considerable degradation in performance compared to conventional detectors.

Attempts have been made to implement zero-crossing detection of the complex valued base band signal instead of zero-crossing detection of a real valued received signal, at an appropriately chosen intermediate frequency (IF). However, despite many advantages, such base band demodulators require a considerable amount of analog circuitry. In contrast IF detectors, including the IF detectors of this invention, are predominantly digital hardware rather than analog circuitry, and consequently benefit enormously from the continuing advances in digital microelectronics.

In order to suppress out-of-band noise and adjacent channel interference, the deployment of analog bandpass filters at the input of the zero-crossing detector is mandatory. Usually, symmetrical bandpass filters with time-bandwidth products in the order of unity are used. Such filters lead to distortions of the received signal and therefore must be considered in the receiver design. Fortunately, since the received perturbation is narrow-band at the bandpass filter output and the modulation index h is smaller than one, frequency modulation (FM) click noise is negligible.

In a preferred embodiment of the present invention, a linear digital filter, developed by setting out from a least squares (LS) approach as detailed below, applied to the output of the digital zero-crossing detector yields a favorable bit error ratio (BER) performance. The improved zero-crossing detector of this invention is sometimes termed a zero-crossing decorrelation detector (ZXDD).

The invention will now be described in more detail by reference to the attached drawings in which like numbers represent like elements.

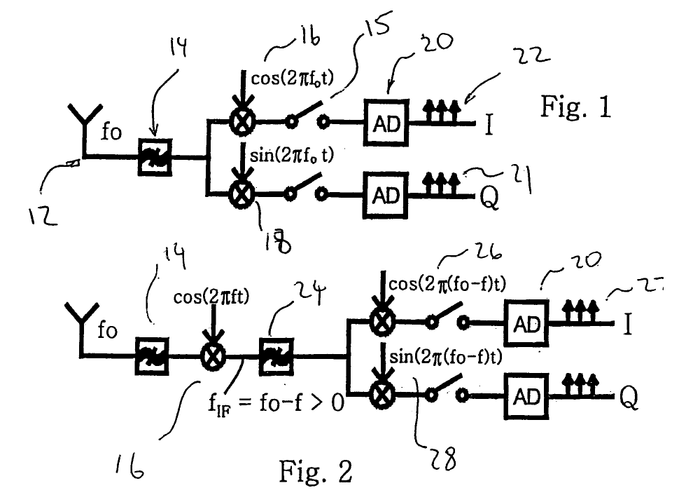

A normal analog receiver, as shown in FIG. 1, comprises an antenna 12, a receiver 14 including appropriate band-pass filters, an in-phase base-band signal 16, threshold detectors 15, a quadrature-phased base-band signal 16, analogue-to-digital (AD) converter 20, and recovered data signal 22. Such systems are capable of high quality demodulation of both in-phase and in-quadrature frequency modulated signals, but require high quality analogue-to-digital (AD)-devices in order to sample the signals with the necessary accuracy.

To overcome the problems with receivers shown in FIG. 1, the incoming signal of modern receivers is multiplied by a sinusoidal signal 16, as shown in FIG. 2, having an intermediate frequency (IF) which is less than the modulation frequency but greater than zero. By using signals with an intermediate frequency the demands on the band-pass filters 24 are reduced compared to the receiver of FIG. 1.

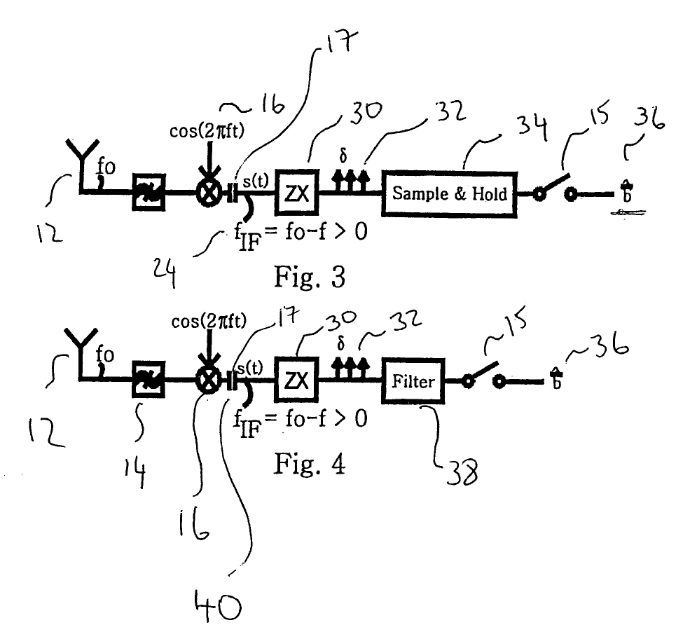

Receivers, as shown in FIG. 3, using Zero-Crossing-Detectors 30 are known as well. A sample-and-hold device 34 is use to retrieve the transmitted signal 36 from the train of zero-crossing points 32. The sample-and-hold device 34 retrieves the transmitted signal 36 by calculating the number of zero-crossings in a pre-defined time interval. In such designs, good receiver performance requires a high resolution for the sampled 6-values.

FIG. 4 shows an exemplary embodiment of the present invention comprising an antenna 12, a receiver 14, a sinusoidal signal 16 having an appropriately chosen intermediate frequency (IF), greater than zero and less than the carrier frequency f0, a pre-filter 40, a zero-crossing detector 30, a train of zero-crossing timings 32, an output filter 30, a threshold detector 15 and a recovered data signal 36.

Pre-filter 40 is necessary in order to suppress out-of-band noise and adjacent channel interference, the deployment of analog bandpass filters at the input of the zero-crossing detector is mandatory. Usually, symmetrical bandpass filters with time-bandwidth products in the order of unity are used. When deploying MSK, such filters lead to distortions of the received signal and therefore must be considered in the receiver design. Fortunately, since the received perturbation is narrow-band at the bandpass filter output and the modulation index h is smaller than one, frequency modulation (FM) click noise is negligible. Such filters have been described in detail by, for instance, Pawula in “Improved performance of coded digital FM”, in IEEE Transactions on Communications, vol. 47 (1999), pp. 1701-1708, the contents of which are hereby incorporated by reference.

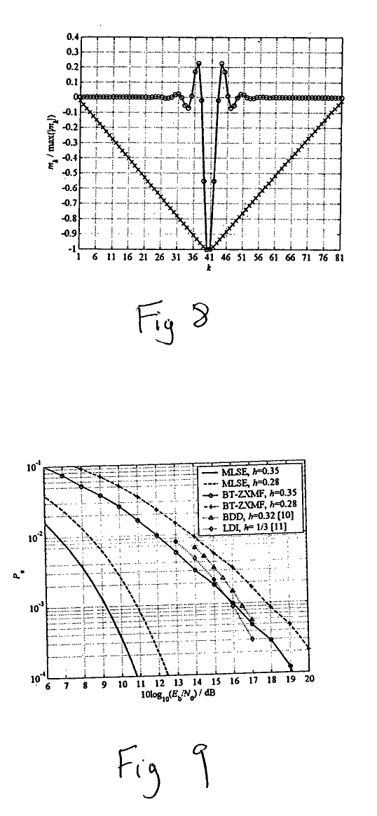

In a preferred embodiment, the output filter 30 is a digital filter having the impulse response illustrated in FIG. 8. The output filter 30 is designed as described in detail in by Scholand et al. in “Advanced intermediate frequency zero-crossing detection of bandpass filtered MSK signals”, IEE Electronics Letters, vol. 39 (2003), pp. 736-738, the contents of which are hereby incorporated by reference.

The design of output filter 30 can also be understood by considering the following system description, in which matrix-vector notation is used. Matrices are denoted as upper case characters in bold face italics, vectors are lower case characters in bold face italics. ( )T•shall denote the matrix or vector transpose. Furthermore, complex-valued variables are underlined.

A Bluetooth radio channel causes slowly varying attenuation and phase shift of the transmitted signal over a single fading path. We can therefore assume that during the transmission of a burst the channel is time invariant. The transmitted burst consists of M data bits dₘ, m=0 . . . (M−1), of bit period T_{b}, represented by the data vector
d=(d₀, d₁ . . . d_{M-1})^{T}, dₘ∈{−1, +1}, m=0 . . . (M−1).

At the receiver 14, the received signal is down-converted to the IF domain by a radio frequency-intermediate frequency (RF-IF) down-conversion unit, which contains mixers, oscillators, etc. This RF-IF down-conversion unit contained in receiver 14 has a band-pass filtering. Its output signal is fed into the zero-crossing detector, a synchronization/sample selection unit and a linear digital filter followed by a threshold detector.

In the preferred embodiment, this bandpass filter is a symmetrical Hamming bandpass filter with double-sided 3 dB bandwidth 1.15/T_{b}. This filter has a time-bandwidth product of approximately 1. Its impulse response can be truncated to a total length of L_{BP}T_{b}=6T_{b}.

At the input of the zero-crossing detector, the received signal with intermediate frequency IF f>0 prevails. Without loss of generality, we assume that IF f is an integer multiple of the bit rate Assuming MSK modulation, with the zero-phase angle φ0 and with the additive white Gaussian noise signal n(t), having zero mean and double-sided spectral noise density N/2, the received MSK signal is given by

$$e ( t ) = \underbrace{\sqrt{\frac{2 {E}_{b}}{{T}_{b}}} {\int }_{t - {L}_{BP} {T}_{b}}^{t} {c}_{BP} ( t - τ ) cos ( 2 π {f}_{IF} τ + π {\sum }_{m = 0}^{M - 1} {d}_{m} q ( τ - m {T}_{b} ) + {φ}_{0} ) ⅆ τ}_{{e}_{u} ( t )} + \underbrace{{\int }_{t - {L}_{BP} {T}_{b}}^{t} {c}_{BP} ( t - τ ) n ( τ ) ⅆ τ}_{{n}_{BP} ( t )} .$$

The first term in (2), is termed the useful MSK signal part. The second term, is a sample function of a zero mean stationary Gaussian process, representing the bandpass noise and interference and having the autocorrelation function

$$R ( τ ) = \frac{{N}_{0}}{2} \cdot [ c ( τ ) * c ( - τ ) ] \cdot cos ( 2 π {f}_{IF} τ ) .$$

Making assumptions detailed in Scholand et al. cited previously, results in the following system equation

$${e}^{\text{?}} \approx \frac{1}{2 {f}_{IF}^{2}} {G}^{\text{?}} d + {{n}^{\text{?}}}_{δ} . \\ \text{?} \text{indicates text missing or illegible when filed}$$

With the MSK frequency impulse g(r), the System matrix is given by

$$\begin{matrix}{g}_{ZX , n} ( τ ) = 〈 rect ( τ / {δ}_{u , n} - 1 / 2 ) / {δ}_{u , n} 〉 * g ( τ ) \\ G = ( \begin{matrix}{g}_{ZX} ( {T}_{g} / 2 ) & {g}_{ZX} ( {T}_{g} / 2 - {T}_{b} ) & L & 0 \\ {g}_{ZX} ( {T}_{g} / 2 + {T}_{b} ) & {g}_{ZX} ( {T}_{g} / 2 ) & L & 0 \\ M & M & O & M \\ 0 & 0 & L & {g}_{ZX} ( {T}_{g} / 2 )\end{matrix} )\end{matrix}$$

With the impulse response of the used bandpass filter c(r), the noise power is given by
σ_{δ}²≈N₀·B(1−{c(τ)*c(−τ)}|_{τ=1/f}_{_{IF}}/{c(τ)*c(−τ)}|_{τ=0})/(4π²f_{IF}²·2E_{b}/T_{b})

As detailed in Scholand et al. cited previously, this can be used to a linear digital filter by using a least squares (LS) approach. It is necessary to find that particular data vector which minimizes the quadratic form. The resulting LS estimator, which is identical to the generalized least squares (GLS) estimator, yields
\hat{d}_{SLS-ZXDD}=−2f_{IF}²\tilde{G}⁻¹\tilde{e}.

The combination of the zero-crossing detector, this LS estimator (a form of digital filter0 and the threshold detector is termed simplified least squares zero-crossing decorrelation detector (SLS-ZXDD), or ZXDD for short.

The LS estimator can be approximated by a time-invariant finite impulse response (FIR) filter. It is sufficient to implement the SLS-ZXDD using a FIR filter length between 3 and 7.

In a further embodiment of the present invention, termed Bluetooth zero-crossing matched filter (BT-ZXMF), the filter may be a decorrelating matched filter (DMF) is given by

$${\hat{d}}_{m} = - \frac{h}{{( {f}_{IF} )}^{2}} \cdot {u}_{m}^{T} {G}^{T} {R}_{i , m}^{- 1} e , \qquad m ∈ \{ 0 , 1 ⋯ ( M - 1 ) \} .$$

Efficient implementations of this DMF are obtained with the approximation

$$m = - \frac{h}{{( {f}_{IF} )}^{2}} \cdot {u}_{m}^{T} {G}^{T} {R}_{i , m}^{- 1} , \qquad m = \text{?} ( M - 1 ) / 2 \text{?} fixed ,$$

$$\text{?} \text{indicates text missing or illegible when filed}$$

BT-ZXMF implementation is described in detail in

In a further embodiment of the present invention, the best linear unbiased estimation (BLUE) which is identical to the minimum variance unbiased (MVU) estimation can be determined by adapting the results already published in Jung, P.: Analyse und Entwurf digitaler Mobilfunksysteme. Stuttgart: Teubner, 1997, and we thus find the zero-forcing block linear equalizer (ZF-BLE)

$${\hat{d}}_{ZXDD} = {( {[ - \frac{1}{2 {f}_{IF}^{2}} ]}^{2} {G}^{T} [ \frac{1}{{σ}_{δ}^{2}} I ] G )}^{- 1} [ - \frac{1}{2 {f}_{IF}^{2}} ] {G}^{T} [ \frac{1}{{σ}_{δ}^{2}} I ] e = - 2 {f}_{IF}^{2} {G}^{- 1} e .$$

The combination of the ZXD, this ZF-BLE and a threshold detector is termed zero-crossing decorrelation detector (ZXDD). The ZF-BLE can be approximated by a finite impulse response (FIR) filter with impulse response vector
m_{ZXDD}=−2f_{IF}²·uₘ^{T}G⁻¹, m=└(M+1)/2┘ fixed,

In a further embodiment of the invention termed termed Bluetooth zero-crossing zero forcing equalizer (BT-ZXZF), the finite impulse response (FIR) filter has the impulse response vector

$$\begin{matrix}{m}_{BT \text{-} ZXZF} = - \frac{{( {f}_{IF} )}^{2}}{h} \cdot {{u}_{m}^{T} ( {G}^{T} {R}_{δ , HP}^{- 1} G )}^{- 1} {G}^{T} {R}_{δ , HP}^{- 1} , \\ m = \text{?} ( M - 1 ) / 2 \text{?} fixed ,\end{matrix}$$

$$\text{?} \text{indicates text missing or illegible when filed}$$

In the case of GFSK modulation [0036] changes. [0037] up to [0050] can be computed with the changed values. The received GFSK signal is given by

$$r ( t ) = {\sqrt{\frac{2 {E}_{b}}{T}} \cdot {\int }_{\text{?} - {OT}_{b}}^{t} {c}_{BP} ( t - τ ) \cdot cos \{ 2 π {f}_{IF} τ + 2 π h {\sum }_{\text{?}}^{{m}^{′}} {d}_{m} q ( t - m {T}_{b} ) + {φ}_{0} \} ⅆ τ}_{\text{?}} + {{\int }_{\text{?}}^{t} {c}_{BP} ( t - τ ) \cdot n ( τ ) ⅆ τ}_{\text{?}}$$

$$\text{?} \text{indicates text missing or illegible when filed}$$

The effect of the bandpass filter can also be neglected for a suboptimal solution:

$$r ( t ) = {\sqrt{\frac{2 {E}_{b}}{T}} \cdot cos \{ 2 π {f}_{IF} τ + 2 π h {\sum }^{{m}^{′}} {d}_{m} q ( t - m {T}_{b} ) + {φ}_{0} \}}_{{\text{?}}_{{r}_{u} ( t )}} + {n ( τ )}_{{\text{?}}_{{n}_{BP} ( t )}}$$

$$\text{?} \text{indicates text missing or illegible when filed}$$

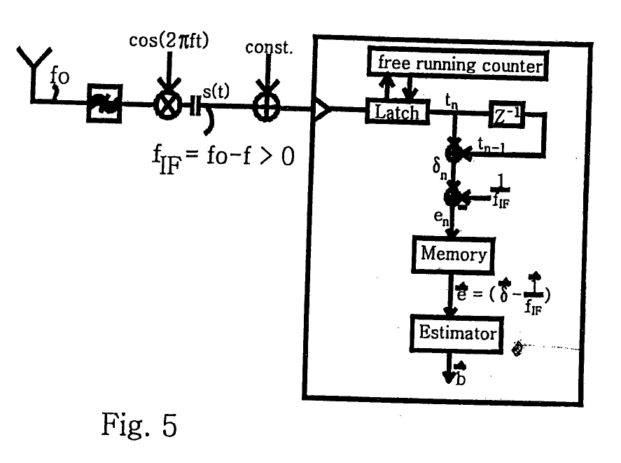

FIG. 5 shows an exemplary zero-crossing receiving circuit embodying the inventive concepts of the present invention implemented as functional modules of an integrated circuit.

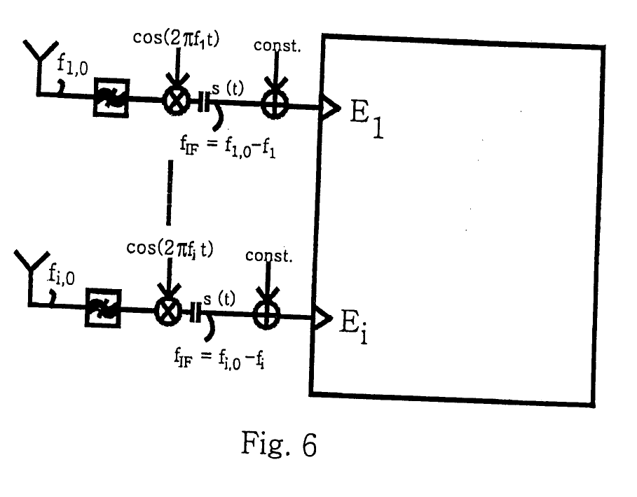

FIG. 6 shows a parallel multi-standard capable zero-crossing receiver.

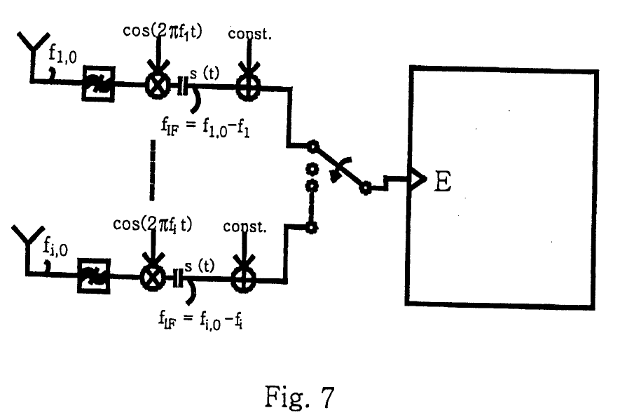

FIG. 7 shows a serial multi-standard capable zero-crossing receiver.

FIG. 8 shows the elements of a representative output filter as described above.

FIG. 9 shows representative results of a receiving circuit embodying the inventive concepts of the present invention.

While the invention has been disclosed in terms of an exemplary embodiment, it will be apparent to one of ordinary skill in the art that many modifications can be made to the disclosed method and apparatus without departing from the spirit of the invention. Therefore, it is the intent of the appended claims to cover all such variations and modifications as may come within the true spirit and scope of this invention.

1. Receiver for modulated incoming signals with a carrier frequency f₀ and a bandwith B, whereby a band-pass filter is limiting the incoming signal and a downstream multiplier is multiplying the bandlinimted signal with a sinusoidal signal with a frequenc f<f₀, whereafter the output signal of the mulitplier s(t) is the input signal of a downstream “Zero-Crossing”-Decoder, whereby the output signal has an intermediate frequency f_{IF}=f₀−f, with f_{IF}>B/2,
characterized by the fact, that
the “Zero-Crossing”-Decoder is part of a Microprocessor, and that the signal s(t) is the input signal to one of the microprocessors inputs (E), whereby the microprocessor has a timer (or counter) which counts with a frequency f_{CL}, whereby f_{CL} is smaller than the intermediate frequency f_{IF}, and the microprocessor is determinating (calculating) the time distances δₙ of the zero-crossings of the input signal using the timer (counter) values.

2. Receiver according to claim 1, wherein a memory holds the values of the time intervals δₙ of one burst.

3. Receiver according to claim 1, wherein a memory holds the values—as a vector e—of the time intervals δₙ each subtracted by the value 1/f_{IF}.

4. Receiver according to claim 1, wherein an estimator (decoder) is estimating the transmitted data by using an approximated linear system model (e=Ad+n) of the transmitting system.

5. Receiver according to claim 4, wherein the estimator calculates the quality of each received data value, whereby the quality is a statement of the probability whether a transmitted data value was correctly transmitted.

6. Receiver according to claim 4 or 5, wherein the estimator is a linear filter, whereby a threshold device is applied to the output of the estimator for detecting the data values.

7. Receiver according to claim 4 or 5, wherein the estimator is a Max-Log-ML detector.

8. Receiver according to claim 1, wherein the frequency f_{CL} is within the parameters of f_{IF}/8<=f_{CL}<f_{μProc}, with f_{μProc} is the frequency of the microprocessor or the timer (counter).

9. Receiver according to claim 1, wherein the input (E) of the microprocessor is a Timer input, counter input or a normal signal input.

10. Receiver according to claim 9, wherein a capacitor is in downstream of the multiplier.

11. Receiver according to claim 9, wherein the signal s(t) is free of direct voltage and that an Offset is added by an adder.

12. Receiver according to claim 9, wherein the receiver comprises more than one band-pass filters and multipliers for receiving multiple incoming signals with different frequencies f_{i,0}, whereby a selector is selectively connecting the signals sᵢ(t) to the input of the microprocessor.

13. Receiver according to claim 9, wherein the receiver comprises more than one band-pass filters and multipliers for receiving multiple incoming signals with different frequencies f_{i,0}, whereby each signal sᵢ(t) is the input signal for an input Eᵢ of the microprocessor.

14. Receiver according to claim 1, wherein the incoming signal is a phase modulated signal, especially modulated with CPM (continuous phase modulation), especially a GSM, Bluetooth or DGPS-signal.

15. Method for data detecting in a transmitting system with continuous phase modulation, wherein the incoming signal is provided in an intermediate frequency interval with a preferred intermediate frequency, and that the incoming signal is limited by a band-pass filter and the bandwidth is approximately the symbol rate, whereby a “Zero-Crossing”-detector transforms the band-limited signal into a sequence of approximately timely equidistant sampling values, which represent the useful (effective) portion of the frequency-response curve which is disturbed by a disturbance, and that the sampling values are interpreted by a linear system model with sampling values in symbol or intermediate frequency cycle, with linear digital filter in downstream of the “Zero-Crossing”-detector, and threshold detection is applied after the digital filter.
